(19) United States
(12) Patent Application Publication
(10) Pub. No.: US 2026/0344370 A1
(43) Pub. Date: Oct. 29, 2026

(54) METHOD FOR FORMING PATTERNED MASK ON SUBSTRATE

(71) Applicant: Tokyo Electron Limited, Tokyo (JP)

(72) Inventors: Michael Murphy, Niskayuna, NY (US); Jodi Grzeskowiak, Schenectady, NY (US)

(21) Appl. No.: 19/193,563

(22) Filed: Apr. 29, 2025

(51) Int. Cl. H10P 76/20

(52) U.S. Cl. CPC H10P 76/204

(57) ABSTRACT

A method includes forming mandrels over a substrate. A first polymer layer is formed over the mandrels. A top surface of the first polymer layer is above top surfaces of the mandrels. The first polymer layer is separated into a second polymer layer and a third polymer layer over the second polymer layer. An interface between the second polymer layer and the third polymer layer is below the top surfaces of the mandrels. The third polymer layer is selectively removed. Free acid is generated in the second polymer layer. The free acid is diffused into the mandrels to form deprotected regions of the mandrels. Remaining regions of the mandrels form protected regions of the mandrels. The protected regions of the mandrels are selectively removed. The second polymer layer is selectively removed. The deprotected regions of the mandrels form a patterned mask over the substrate.

### TECHNICAL FIELD

The present disclosure relates generally to methods for processing a substrate, and, in particular embodiments, to methods for forming a patterned mask on a substrate.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

Photolithography is a common patterning method in semiconductor fabrication. A photolithography process may start by exposing a coating of photoresist comprising a radiation-sensitive material to a pattern of actinic radiation to define a relief pattern. For example, in the case of positive photoresist, irradiated portions of the photoresist may be dissolved and removed by a developing step using a developing solvent, forming the relief pattern of the photoresist. The relief pattern then may be transferred to a target layer below the photoresist or an underlying hard mask layer formed over the target layer. Innovations on photolithographic techniques may be needed to satisfy the cost and quality requirements for patterning of nanoscale features.

### SUMMARY

In accordance with an embodiment of the present disclosure, a method includes: forming mandrels over a substrate; forming a first polymer layer over the mandrels, a top surface of the first polymer layer being above top surfaces of the mandrels; separating the first polymer layer into a second polymer layer and a third polymer layer over the second polymer layer, an interface between the second polymer layer and the third polymer layer being below the top surfaces of the mandrels; selectively removing the third polymer layer; generating free acid in the second polymer layer; diffusing the free acid into the mandrels to form deprotected regions of the mandrels, remaining regions of the mandrels forming protected regions of the mandrels; selectively removing the protected regions of the mandrels; and selectively removing the second polymer layer, where the deprotected regions of the mandrels form a patterned mask over the substrate.

In accordance with another embodiment of the present disclosure, a method includes: depositing mandrels over a substrate, the mandrels being separated by openings; depositing a first polymer layer over the mandrels, the first polymer layer overfilling the openings; separating the first polymer layer into a second polymer layer and a third polymer layer over the second polymer layer, an interface between the second polymer layer and the third polymer layer being below top surfaces of the mandrels; selectively removing the third polymer layer suing a first solvent; generating free acid in the second polymer layer; diffusing the free acid into the mandrels to form deprotected regions of the mandrels, remaining regions of the mandrels forming protected regions of the mandrels; selectively removing the protected regions of the mandrels using a second solvent different from the first solvent; and selectively removing the second polymer layer using a third solvent different from the first solvent, where the deprotected regions of the mandrels form a patterned mask over the substrate.

In accordance with yet another embodiment of the present disclosure, a method includes: forming mandrels over a substrate; forming a first polymer layer over the mandrels, a top surface of the first polymer layer being above top surfaces of the mandrels; separating the first polymer layer into a second polymer layer and a third polymer layer over the second polymer layer, an interface between the second polymer layer and the third polymer layer being at the top surfaces of the mandrels; selectively removing the third polymer layer using a first solvent; generating free acid in the second polymer layer; diffusing the free acid into the mandrels to form deprotected regions of the mandrels, remaining regions of the mandrels forming protected regions of the mandrels; and selectively removing the deprotected regions of the mandrels using a second solvent, where the second polymer layer and the protected regions of the mandrels form a patterned mask over the substrate.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A-1I illustrate cross-sectional views of intermediate stages in the manufacturing of a patterned mask over a substrate in accordance with various embodiments;

FIGS. 2A-2H illustrate cross-sectional views of intermediate stages in the manufacturing of a patterned mask over a substrate in accordance with various embodiments;

FIGS. 3A-3H illustrate cross-sectional views of intermediate stages in the manufacturing of a patterned mask over a substrate in accordance with various embodiments;

FIG. 4 illustrates a flow diagram of a method for forming a patterned mask over a substrate in accordance with various embodiments;

FIG. 5 illustrates a flow diagram of a method for forming a patterned mask over a substrate in accordance with various embodiments; and

FIG. 6 illustrates a flow diagram of a method for forming a patterned mask over a substrate in accordance with various embodiments.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

In an embodiment, a method for forming a patterned mask over a substrate is provided. The method includes forming mandrels over a substrate and then forming a first polymer layer over the mandrels. The first polymer layer separates into a second polymer layer and a third polymer layer. Free acid is generated in the second polymer layer and diffused into the mandrels, creating deprotected regions in the mandrels. The method then selectively removes the third polymer layer, protected regions of the mandrels, and the second polymer layer, leaving the deprotected regions of the mandrels to form a patterned mask over the substrate.

In other embodiments, the method includes the option to generate and diffuse free acid during a post-deposition bake process. This can simplify the overall process by combining two steps (acid generation/diffusion and baking) into one, improving throughput and reducing process variability. In yet other embodiments, a variation of the method includes selectively removing the deprotected regions of the mandrels instead of the protected regions of the mandrels. In such embodiments, the second polymer layer and the protected regions of the mandrels form the patterned mask over the substrate.

In various embodiments, the disclosed methods allow for control over dimensions (e.g., width and height) of features of the resulting patterned mask. In particular, the first polymer layer that separates into a second polymer layer and a third polymer layer allows for controlling the height of features of the resulting patterned mask. The disclosed methods may be implemented using existing photolithography and etching equipment, reducing the need for significant capital investment while offering improved patterning capabilities. The flexibility in process order, particularly regarding the removal of the third polymer layer, provides opportunities for process optimization based on specific material interactions or device requirements.

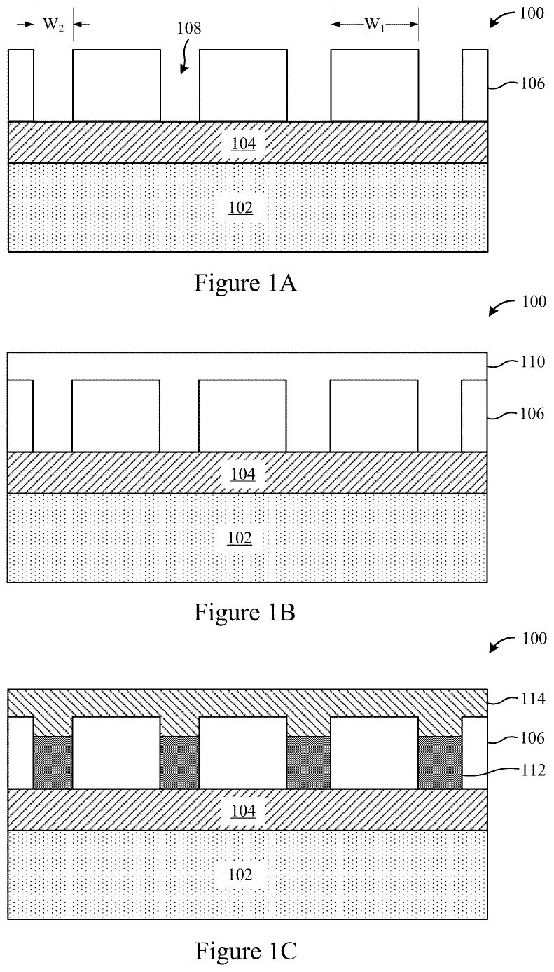

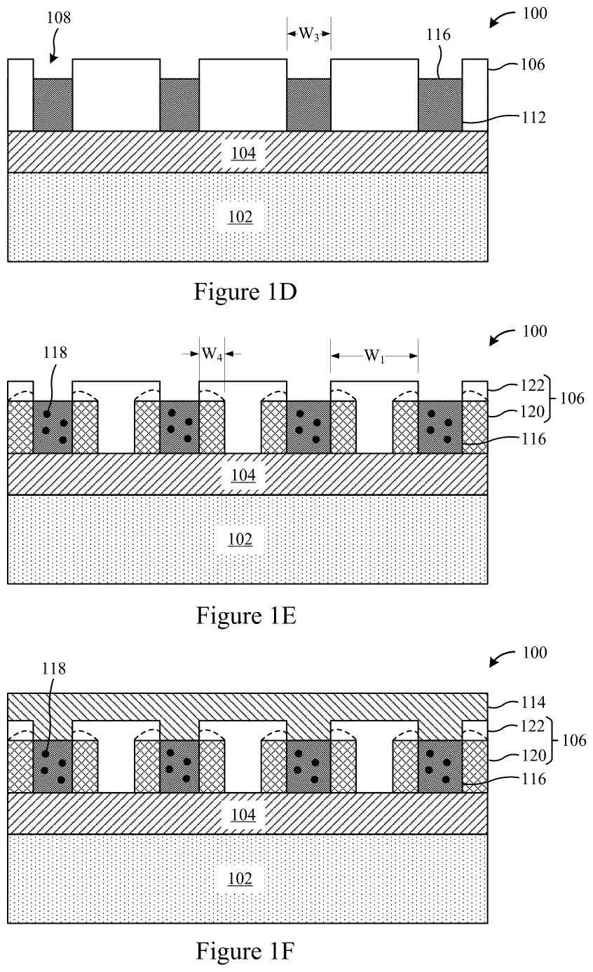

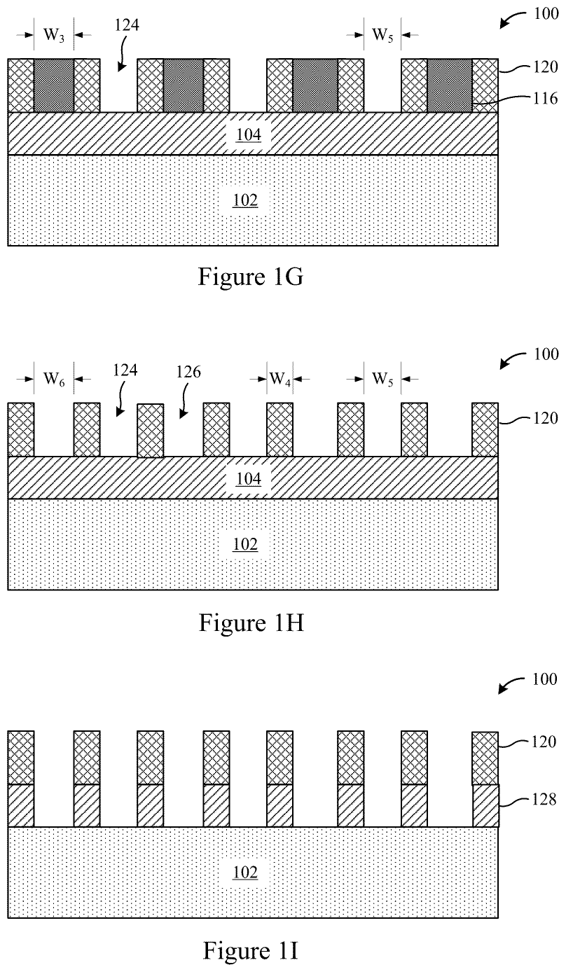

FIGS. 1A-1I illustrate cross-sectional views of intermediate stages in the manufacturing of a patterned mask over a substrate in accordance with various embodiments. In FIG. 1A, a semiconductor structure 100 is illustrated. The semiconductor structure 100 may include the substrate 102. The substrate 102 may comprise layers of semiconductors suitable for various microelectronics. In one or more embodiments, the substrate 102 may be a silicon wafer, or a silicon-on-insulator (SOI) wafer. In certain embodiments, the substrate 102 may comprise a silicon germanium wafer, silicon carbide wafer, gallium arsenide wafer, gallium nitride wafer, or other compound semiconductors. In other embodiments, the substrate 102 may comprise heterogeneous layers such as silicon germanium on silicon, gallium nitride on silicon, silicon carbon on silicon, or layers of silicon on a silicon or SOI substrate.

In some embodiments, the substrate 102 may further include semiconductor devices or semiconductor structures and may be formed in any suitable manner, including using any suitable combination of wet and/or dry deposition and etch techniques. In such embodiments, the substrate 102 may include isolation regions such as shallow trench isolation (STI) regions, diffusion regions, as well as other regions formed therein.

In some embodiments, a target layer 104 is formed over the substrate 102. The target layer 104 represents a layer that will be subsequently patterned. In one or more embodiments, the target layer 104 may comprise materials such as silicon, silicon oxynitride, organic materials, non-organic materials, or amorphous carbon. In an embodiment, the target layer 104 may be a silicon bottom anti-reflective coating (Si-BARC), which can enhance the precision of subsequent patterning steps. The target layer 104 may also serve as a mask layer, comprising either a single hard mask or a stacked hard mask. In the case of a stacked hard mask, it may consist of two or more layers of different materials. For instance, in a two-layer configuration, the first layer might comprise a metal-based material such as titanium nitride, titanium, tantalum nitride, tantalum, tungsten-based compounds, ruthenium-based compounds, or aluminum-based compounds. The second layer, in contrast, might be a dielectric layer composed of materials like silicon dioxide, silicon nitride, silicon oxynitride, silicon carbide, amorphous silicon, or polycrystalline silicon. In other embodiments, the target layer 104 may be a dielectric material, a conductive material, or a semiconductor material, depending on the specific application requirements.

The deposition of the target layer 104 may be achieved through various suitable processes. In some embodiments, the target layer 104 may be deposited using spin-on coating techniques, chemical vapor deposition (CVD), atomic layer deposition (ALD), plasma-enhanced CVD (PECVD), plasma-enhanced ALD (PEALD), a combination thereof, or the like. The choice of deposition method depends on factors such as the desired thickness, uniformity, and material properties of the target layer 104.

In some embodiments, mandrels 106 are formed over the target layer 104. The mandrels 106 may be separated by openings 108. The openings 108 define areas where the underlying target layer 104 is exposed. The mandrels 106 may have a width W₁ and the openings 108 may have a width W₂. The width W₁ may be same as or different from the width W₂. In some embodiments, the mandrels 106 may be formed by forming a photoresist layer (not shown) over the target layer 104 and patterning the photoresist layer using suitable photolithographic techniques. The photoresist layer may comprise a positive-tone photoresist or a negative-tone photoresist. The photoresist layer may be deposited on the target layer 104 in any suitable manner. In some embodiments, the photoresist layer may be deposited by spin-coating, spray-coating, dip-coating, roll-coating, CVD, ALD, a combination thereof, or other suitable processes.

In various embodiments, the photoresist layer may comprise an agent-generating ingredient that, in response to a suitable agent-activation trigger (e.g., heat or radiation), generates a solubility-changing agent (e.g., an acid). Example agent-generating ingredients may include a thermal-acid generator (TAG) that is configured to generate an acid in response to heat or a photo-acid generator (PAG) that is configured to generate an acid in response to actinic radiation.

After forming the photoresist layer, a reticle (not shown) is disposed over the photoresist layer. The reticle may be used to modulate a dose (or an intensity) of a radiation (e.g., actinic radiation) that is used to expose the photoresist layer. In such embodiments, the reticle may comprise regions of different transparency to the radiation (e.g., opaque and transparent regions). The photoresist layer is then subject to an exposure step through the reticle. The radiation exposes exposed regions of the photoresist layer while unexposed (or unmodified) regions of the photoresist layer are protected by the reticle. The exposure step may be performed using a photolithographic technique such as dry lithography (e.g., using 193 dry lithography), immersion lithography (e.g., using 193 nanometer immersion lithography), i-line lithography (e.g., using 365 nanometer wavelength UV radiation for exposure), H-line lithography (e.g., using 405 nanometer wavelength UV radiation for exposure), extreme UV (EUV) lithography, deep UV (DUV) lithography, or any suitable photolithography technology.

In some embodiments, the radiation generates a free acid in the exposed regions of the photoresist layer. The free acid may be generated from the PAG that is present in the photoresist layer under the influence of the radiation. The free acid may react with the material of the photoresist layer and alter the solubility of the exposed regions of the photoresist layer. Subsequently, the exposed regions of the photoresist layer are removed by performing a developing process using a suitable developer (e.g., positive-tone developer). The developing process forms the openings 108 in the photoresist layer that expose portions of the target layer 104. The unexposed regions of the photoresist layer form the plurality of mandrels 106.

In FIG. 1B, a first polymer layer 110 is deposited over the mandrels 106. The first polymer layer 110 may overfill the openings 108 (see FIG. 1A) such that a top surface of the first polymer layer 110 is above top surfaces of the mandrels 106. In some embodiments, the first polymer layer 110 may comprise of a material that can separate into two distinct layers in subsequent processing steps. For example, the first polymer layer 110 may comprise a mixture of a first polymer material and second polymer material, such that the first polymer material and the second material have different physicochemical properties (e.g., different surface energies). In some embodiments, the first polymer material may comprise a polymer comprising a combination of monomer units including structures of moderate polarity such as hydroxy styrene, methyl methacrylate, and methyl acrylic acid, a combination thereof, or the like, and the second polymer material may comprise a polymer comprising a polymer comprising a combination of monomer units including structures of moderate polarity such as styrene, hydroxystyrene, methyl methacrylate, and methacrylic acid, a combination thereof, or the like, or a combination of monomer units including monomer units comprising acid labile groups such as t-butyloxycarbonyl (t-BOC), dioxolane (acetal), butylactone, a combination thereof, or the like. In some embodiments, the first polymer material may comprise free acid, or an agent-generating ingredient, such as a TAG or PAG. In some embodiments, the second polymer material may comprise free acid, or an agent-generating ingredient, such as a TAG or PAG, or may be free from free acid and the agent-generating ingredient.

In some embodiments, the first polymer layer 110 may be deposited using techniques such as spin coating, CVD, ALD, a combination thereof, or the like. The choice of deposition technique may depend on factors such as the desired thickness of the first polymer layer 110, its composition, and compatibility with the mandrels 106.

In FIG. 1C, in some embodiments, the first polymer layer 110 (see FIG. 1B) separates into a second polymer layer 112 comprising the first polymer material and a third polymer layer 114 comprising a second polymer material, such that the third polymer layer 114 is over the second polymer layer 112 and the mandrels 106. The second polymer layer 112 may be also referred to as an acid trim layer and the third polymer layer 114 may be also referred to as an embedded barrier layer. In some embodiments, this separation may occur due to differences in the physicochemical properties (e.g., surface energy) of the components in the first polymer layer 110. The relative contents of the first polymer material and the second polymer material within the first polymer layer 110 may control thicknesses of the second polymer layer 112 and the third polymer layer 114 and a position of an interface between the second polymer layer 112 and the third polymer layer 114.

In the illustrated embodiment, the interface between the second polymer layer 112 and the third polymer layer 114 is below top surfaces of the mandrels 106, the second polymer layer 112 partially fills the openings 108 (see FIG. 1A) and the third polymer layer 114 is formed over the second polymer layer 112 and the mandrels 106. In some embodiments, the first polymer layer 110 (see FIG. 1B) may be self-separated into the second polymer layer 112 and the third polymer layer 114. In other embodiments, the separation of the first polymer layer 110 (see FIG. 1B) into the second polymer layer 112 and the third polymer layer 114 may be induced by a thermal treatment, exposure to specific solvents, or other processing conditions.

In some embodiments, a post-deposition bake process may be performed to remove any solvents and stabilize the second polymer layer 112 and the third polymer layer 114. The post-deposition bake process may be performed at a process temperature in a range from 75 °C to 100 °C for a process time in a range from 30 seconds to 180 seconds. In the illustrated embodiment, no free acid is generated in the second polymer layer 112 and the third polymer layer 114 and/or diffused from the second polymer layer 112 and the third polymer layer 114 into the mandrels 106 during the post-deposition bake process. In such embodiment, the second polymer layer 112 and the third polymer layer 114 may be free from free acid and a TAG, or may comprise a TAG that has an activation temperature that is greater than the process temperature of the post-deposition bake process.

In FIG. 1D, the third polymer layer 114 (see FIG. 1C) is selectively removed, leaving the second polymer layer 112 and the mandrels 106 substantially intact. Portions of the second polymer layer 112 within the openings 108 form mandrels 116. Accordingly, the mandrels 116 have a width W₃ which is equal to the width W₂ of the openings 108. Furthermore, in the illustrated embodiment, a height of the mandrels 116 is less than a height of the mandrels 106. In some embodiments, the selective removal of the third polymer layer 114 (see FIG. 1C) may be accomplished using a first solvent that preferentially dissolves or etches the third polymer layer 114 without substantially affecting the mandrels 106 and 116. The choice of the first solvent depends on the specific compositions of the mandrels 106 and 116, and the third polymer layer 114. In an embodiment, tetramethylammonium hydroxide (TMAH) may be used as the first solvent for the selective removal process. In some embodiments, the selective removal of the third polymer layer 114 (see FIG. 1C) allows for controlling the height of the mandrels 116 and subsequent modifications to be made to the mandrels 106 and 116 without interference from the upper polymer layer (e.g., the third polymer layer 114).

In FIG. 1E, free acid 118 is generated in the mandrels 116. In some embodiments, when the mandrels 116 comprise a TAG, the acid generation process may be performed by a first thermal treatment that is performed at a process temperature that is greater than an activation temperature of the TAG. The first thermal treatment may be performed at a process temperature in a range from 100 °C to 150 °C for a process time in a range from 15 seconds to 120 seconds. The process temperature and/or the process time of the thermal treatment may be tuned to control a concentration of the free acid 118 in the mandrels 116.

In other embodiments, when the mandrels 116 comprise a PAG, the acid generation process may be performed by exposing the mandrels 116 to a suitable radiation (e.g., actinic radiation). In such embodiments, a mask may be formed over the mandrels 106 to protect the mandrels 106 from the effects of the radiation. A dose and/or an exposure time of the radiation exposure process may be tuned to control the concentration of the free acid 118 in the mandrels 116.

In some embodiments, following the generation of the free acid 118, the free acid 118 may diffuse from the mandrels 116 into the mandrels 106. The diffused free acid 118 reacts with the material of the mandrels 106 and creates deprotected regions 120 within the mandrels 106. Remaining regions of the mandrels 106 form protected regions 122 of the mandrels 106. The deprotected regions 120 of the mandrels 106 may have different chemical properties (e.g., solubility in various solvents) compared to the protected regions 122 of the mandrels 106. The diffusion process may be performed by a second thermal treatment. The second thermal treatment may be performed at a process temperature in a range from 100 °C to 150 °C for a process time in a range from 15 seconds to 120 seconds. In some embodiments, the second thermal treatment may be performed using process parameters (e.g., process temperature and/or process time) different from the first thermal treatment. In other embodiments, the second thermal treatment may be performed using same process parameters (e.g., process temperature and/or process time) as the first thermal treatment.

In some embodiments, the acid generation and diffusion processes may be performed by a single thermal treatment such as the first thermal treatment. In other embodiments, the acid generation process may be performed by the first thermal treatment and the acid diffusion process may be performed by the second diffusion process different from the first diffusion process. In yet other embodiments, the acid generation process may be performed by a radiation exposure and the acid diffusion process may be performed by the second diffusion process.

A width W₄ of the deprotected regions 120 of the mandrels 106 may be controlled by tuning a concentration of the free acid 118, diffusion coefficients of the free acid 118 in the mandrels 106 and 116, a process temperature of the thermal treatment, and/or a process time of the thermal treatment. In some embodiments, the width W₄ may be controlled such that the width W₄ is less than a half of the width W₁ of the mandrels 106.

The height of the deprotected regions 120 of the mandrels 106 may be controlled by tuning the height of the mandrels 116, which in turn is controlled by tuning the composition of the first polymer layer 110 (see FIG. 1B). Based on diffusion properties of the free acid 118 within the mandrels 106, a shape of top surfaces of the deprotected regions 120 of the mandrels 106 may be altered. In some embodiments, the top surfaces of the deprotected regions 120 of the mandrels 106 may be substantially flat or planar. In other embodiments, the top surfaces of the deprotected regions 120 of the mandrels 106 may be curved as illustrated by dashed lines in FIG. 1E.

FIG. 1F illustrates an alternative embodiment, where the third polymer layer 114 is removed after the generation and diffusion of the free acid 118. In such embodiments, the third polymer layer 114 may be free from free acid and an agent-generating ingredient, such as a TAG. In some embodiments, the free acid 118 may be generated within the mandrels 116 and diffused into the mandrels 106 as described above with reference to FIG. 1E, and the description is repeated herein. After the formation of the deprotected regions 120 of the mandrels 106, the third polymer layer 114 is selectively removed to obtain the structure of FIG. 1E. In some embodiments, the third polymer layer 114 may be selectively removed as described above with reference to FIG. 1D, and the description is not repeated herein.

In FIG. 1G, the protected regions 122 of the mandrels 106 (see FIG. 1E) are selectively removed, leaving behind the mandrels 116 and the deprotected regions 120 of the mandrels 106. The removal process forms openings 124 that expose the target layer 104. The openings 124 may have a width W₅, which is equal to a difference between the width W₁ of the mandrels 106 and twice the width W₄ of the deprotected regions 120 of the mandrels 106 (see FIG. 1E).

In some embodiments, the selective removal may be accomplished using a second solvent. The second solvent may be different from the first solvent. The second solvent may be a negative-tone solvent and may be chosen to preferentially dissolve or etch away the protected regions 122 of the mandrels 106 (see FIG. 1E) while leaving the mandrels 116 and the deprotected regions 120 of the mandrels 106 substantially intact. In some embodiments, the second solvent may comprise methyl isobutyl carbinol (MIBC), isoamyl ether (IAE), Isobutyl Isobutyrate (IBIB), a combination thereof, or the like.

In FIG. 1H, the mandrels 116 (see FIG. 1G) are selectively removed, leaving behind the deprotected regions 120 of the mandrels 106. The removal process forms openings 126 that expose the target layer 104. In some embodiments, the openings 126 may have a width W₆, which is equal to the width W₂ of the openings 108 (see FIG. 1A) and the width W₃ of the mandrels 116 (see FIG. 1G). In some embodiments, the selective removal may be accomplished using a third solvent. The third solvent may be chosen to preferentially dissolve or etch away the mandrels 116 (see FIG. 1G) while leaving the deprotected regions 120 of the mandrels 106 substantially intact. In some embodiments, the third solvent may comprise methyl isobutyl carbinol (MIBC), isoamyl ether (IAE), Isobutyl Isobutyrate (IBIB), a combination thereof, or the like.

In some embodiments, materials of the mandrels 106 (see FIG. 1E) and the mandrels 116 (see FIG. 1G) may be chosen such that the third solvent used for removing the mandrels 116 (see FIG. 1G) may be the same as the second solvent used for removing the protected regions 122 of the mandrels 106 (see FIG. 1E). In other embodiments, the third solvent may be different from the second solvent.

After the selective removal, the deprotected regions 120 of the mandrels 106 form a patterned mask over the target layer 104. The dimensions (e.g., width W₄) of the deprotected regions 120 of the mandrels 106 may be smaller than the dimensions (e.g., width W₂) of the openings 108 (see FIG. 1A). This reduction in feature size is a result of the controlled acid diffusion process and can be used to achieve patterns with dimensions smaller than those directly achievable through the initial lithography process.

In some embodiments, the width W₄ of the deprotected regions 120 of the mandrels 106 may be tuned such that a desired ratio of the width W₅ of the openings 124 to the width W₆ of the openings 126 is achieved. In one embodiment, the width W₄ of the deprotected regions 120 of the mandrels 106 may be tuned such that the width W₅ of the openings 124 is same as the width W₆ of the openings 126. In some embodiments, in addition to the width W₄, the width W₁ of the mandrels 106 and the width W₂ of the openings 108 (see FIG. 1A) may be also tuned such that the widths W₄, W₅, and W₆ are equal to each other.

In FIG. 1I, a pattern defined by the patterned mask (formed by the deprotected regions 120 of the mandrels 106) is transferred to the target layer 104 (see FIG. 1H), forming a patterned target layer 128. In some embodiments, the pattern transfer may be accomplished through an etching process. The etching process selectively removes portions of the target layer 104 (see FIG. 1H) that are not protected by the patterned mask, resulting in the formation of the patterned target layer 128. In some embodiments, the etching process may be a dry etching technique such as reactive ion etching (RIE), plasma etching, or ion beam etching. In other embodiments, wet etching techniques may be employed.

In some embodiment, the pattern transfer process may be followed by the removal of any remaining deprotected regions 120. The removal can be accomplished using suitable solvents, plasma ashing techniques, or the like leaving the patterned target layer 128 on the substrate 102. The resulting structure, with the patterned target layer 128, may form a component of a semiconductor device. Depending on the specific application, the patterned target layer 128 amy represent various elements of a semiconductor device, such as gate electrodes, interconnect lines, or other functional structures.

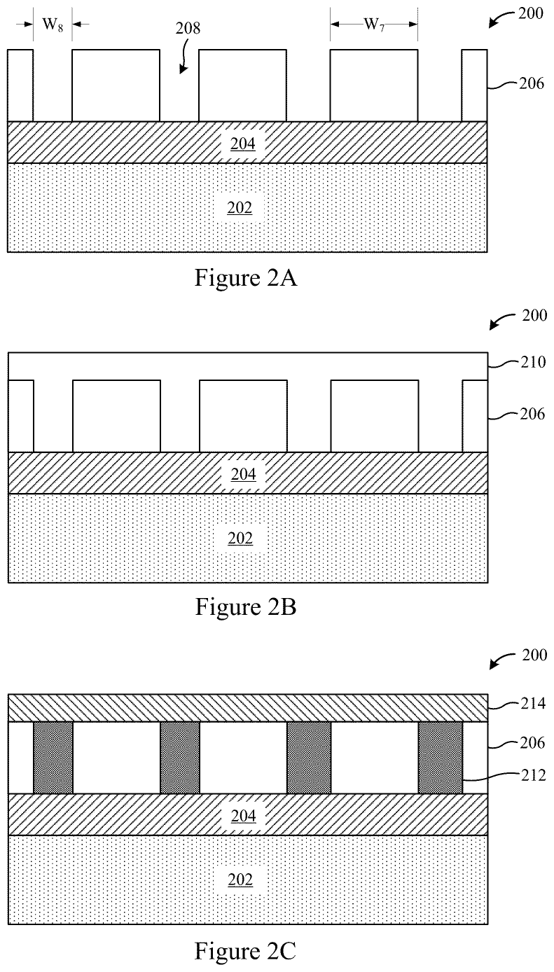

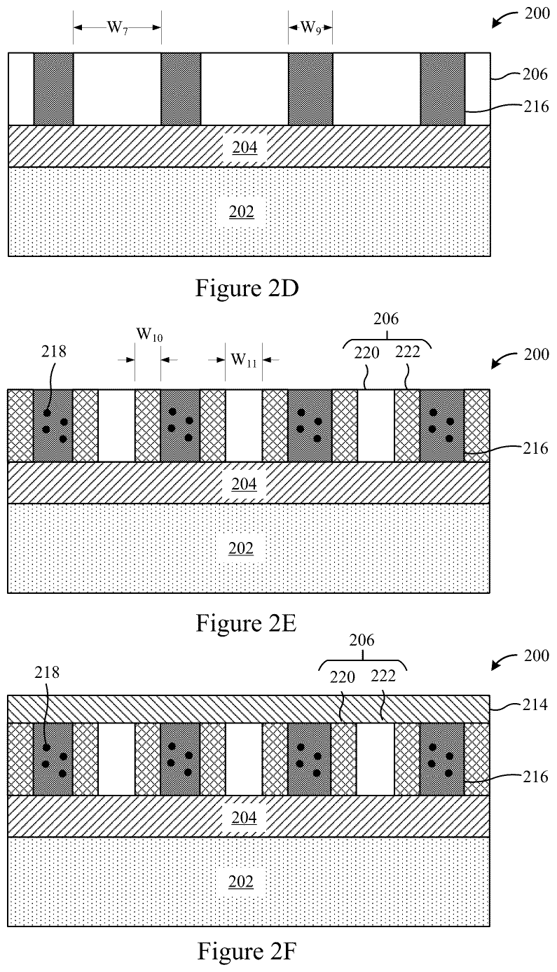

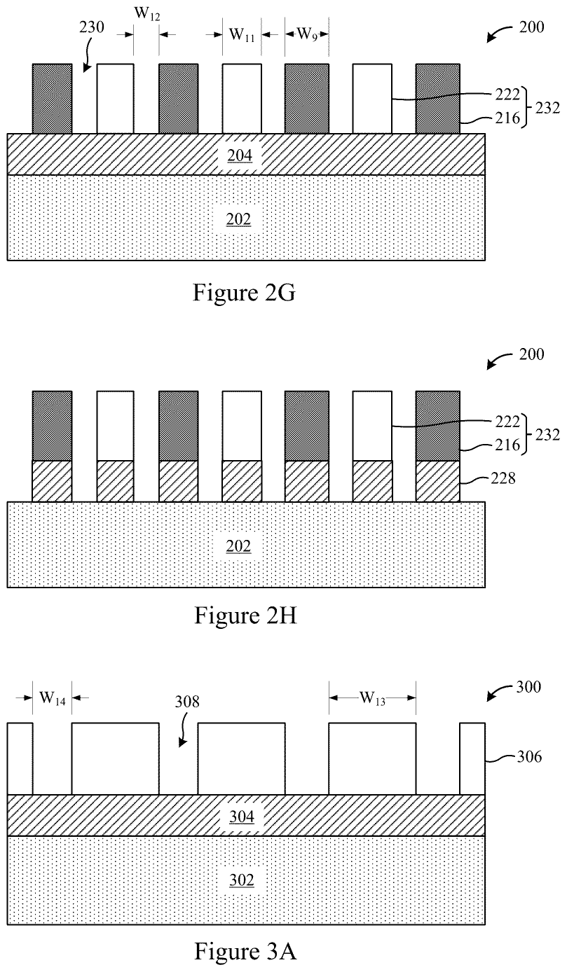

FIGS. 2A-2H illustrate cross-sectional views of intermediate stages in the manufacturing of a patterned mask over a substrate in accordance with various embodiments. Unless otherwise indicated, features 2xx may be similar to features 1xx of FIGS. 1A-1I, may be formed using materials and methods that are similar to those described above with reference to FIGS. 1A-1I, and descriptions of the similar features are not repeated herein.

In FIG. 2A, a semiconductor structure 200 is illustrated. The semiconductor structure 200 may include a substrate 202, a target layer 204 over the substrate 202 and a plurality of mandrels 206 over the target layer 204. The mandrels 206 may be separated by openings 208. The openings 208 define areas where the underlying target layer 204 is exposed. The mandrels 206 may have a width W₇ and the openings 208 may have a width W₈. The width W₇ may be same as or different from the width W₈.

In some embodiments, the dimensions, materials, and specific arrangements of the features of FIG. 2A may differ from those in FIG. 1A, depending on the particular application and desired outcomes of the patterning process. For example, the width and depth of the openings 208 and the width and height of the mandrels 206 may be adjusted to achieve different feature sizes in the final patterned structure.

In FIG. 2B, a first polymer layer 210 is formed over the mandrels 206. In the illustrated embodiment, the first polymer layer 210 overfills the openings 208, such that a top surface of the first polymer layer 210 is above top surfaces of the mandrels 206. This step is similar to the process described in FIG. 1B, but there may be differences in the specific properties or composition of the first polymer layer 210. For example, the first polymer layer 210 may comprise a mixture of a first polymer material and a second polymer material, such that relative amounts of the first polymer material and the second polymer material may be different from those of the first polymer layer 110 (see FIG. 1B). The first polymer material and the second material may have different physicochemical properties (e.g., different surface energies). In some embodiments, the first polymer material may comprise a polymer comprising a combination of monomer units including structures of moderate polarity such as hydroxy styrene, methyl methacrylate, and methyl acrylic acid, a combination thereof, or the like, and the second polymer material may comprise a polymer comprising a polymer comprising a combination of monomer units including structures of moderate polarity such as styrene, hydroxystyrene, methyl methacrylate, and methacrylic acid, a combination thereof, or the like, or a combination of monomer units including monomer units comprising acid labile groups such as t-butyloxycarbonyl (t-BOC), dioxolane (acetal), butylactone, a combination thereof, or the like. In some embodiments, the first polymer material may comprise free acid, or an agent-generating ingredient, such as a TAG or PAG. In some embodiments, the second polymer material may comprise free acid, or an agent-generating ingredient, such as a TAG or PAG, or may be free from free acid and the agent-generating ingredient.

In FIG. 2C, the first polymer layer 210 (see FIG. 2B) separates into a second polymer layer 212 comprising the first polymer material and a third polymer layer 214 comprising a second polymer material, such that the third polymer layer 214 is over the second polymer layer 212. The second polymer layer 212 may be also referred to as an acid trim layer and the third polymer layer 214 may be also referred to as an embedded barrier layer. In some embodiments, this separation may occur due to differences in the physicochemical properties (e.g., surface energy) of the components in the first polymer layer 210. The relative contents of the first polymer material and the second polymer material within the first polymer layer 210 may control the thicknesses of the second polymer layer 212 and the third polymer layer 214 and a position of an interface between the second polymer layer 212 and the third polymer layer 214.

In the illustrated embodiment, the interface between the second polymer layer 212 and the third polymer layer 214 is at the top surfaces of the mandrels 206, such that the second polymer layer 212 fully fills the openings 208 (see FIG. 2A) and the third polymer layer 214 is formed over the second polymer layer 212 and the mandrels 206. In some embodiments, the first polymer layer 210 (see FIG. 2B) may be self-separated into the second polymer layer 212 and the third polymer layer 214. In other embodiments, the separation of the first polymer layer 210 (see FIG. 2B) into the second polymer layer 212 and the third polymer layer 214 may be induced by a thermal treatment, exposure to specific solvents, or other processing conditions.

In some embodiments, a post-deposition bake process may be performed to remove any solvents and stabilize the second polymer layer 212 and the third polymer layer 214. The post-deposition bake process may be performed at a process temperature in a range from 75 °C to 100 °C for a process time in a range from 30 seconds to 180 seconds. In the illustrated embodiment, no free acid is generated in the second polymer layer 212 and the third polymer layer 214 and/or diffused from the second polymer layer 212 and the third polymer layer 214 into the mandrels 206 during the post-deposition bake process. In such embodiment, the second polymer layer 212 and the third polymer layer 214 may be free from free acid and a TAG, or may comprise a TAG that has an activation temperature that is greater than the process temperature of the post-deposition bake process.

In FIG. 2D, the third polymer layer 214 (see FIG. 2C) is selectively removed, leaving the second polymer layer 212 (see FIG. 2C) and the mandrels 206 substantially intact. Portions of the second polymer layer 212 within the openings 208 (see FIG. 2A) form mandrels 216. Accordingly, the mandrels 216 may have a width W₉ that is equal to the width W₈ of the openings 208 (see FIG. 2A). Furthermore, in the illustrated embodiment, a height of the mandrels 216 is same as a height of the mandrels 206. In some embodiments, the selective removal of the third polymer layer 214 may be accomplished using a first solvent that preferentially dissolves or etches the third polymer layer 214 without substantially affecting the second polymer layer 212 and the mandrels 206. The choice of the first solvent depends on the specific compositions of the mandrels 206 and 216, and the third polymer layer 214 (see FIG. 2C). In an embodiment, tetramethylammonium hydroxide (TMAH) may be used as the first solvent for the selective removal process. In some embodiments, the selective removal of the third polymer layer 214 (see FIG. 2C) allows for subsequent modifications to be made to the mandrels 206 and 216 without interference from the upper polymer layer (e.g., the third polymer layer 214).

In FIG. 2E, free acid 218 is generated in the mandrels 216. In some embodiments, when the mandrels 216 comprise a TAG, the acid generation process may be performed by a first thermal treatment that is performed at a process temperature that is greater than an activation temperature of the TAG. The first thermal treatment may be performed at a process temperature in a range from 100 °C to 150 °C for a process time in a range from 15 seconds to 120 seconds. The process temperature and/or the process time of the thermal treatment may be tuned to control a concentration of the free acid 218 in the mandrels 216.

In other embodiments, when the mandrels 216 comprise a PAG, the acid generation process may be performed by exposing the mandrels 216 to a suitable radiation (e.g., actinic radiation). In such embodiments, a mask may be formed over the mandrels 206 to protect mandrels 206 from the effects of the radiation. A dose and/or an exposure time of the exposure process may be tuned to control the concentration of the free acid 218 in the mandrels 216.

In some embodiments, following the generation of the free acid 218, the free acid 218 may diffuse from the mandrels 216 into the mandrels 206. The diffused free acid 218 reacts with the material of the mandrels 206 and creates deprotected regions 220 within the mandrels 206. Remaining regions of the mandrels 206 form protected regions 222 of the mandrels 206. The deprotected regions 220 of the mandrels 206 may have different chemical properties (e.g., solubility in various solvents) compared to the protected regions 222 of the mandrels 206. The diffusion process may be performed by a second thermal treatment. The second thermal treatment may be performed at a process temperature in a range from 100 °C to 150 °C for a process time in a range from 15 seconds to 120 seconds. In some embodiments, the second thermal treatment may be performed using process parameters (e.g., process temperature and/or process time) different from the first thermal treatment. In other embodiments, the second thermal treatment may be performed using sane process parameters (e.g., process temperature and/or process time) as the first thermal treatment.

In some embodiments, the acid generation and diffusion processes may be performed by a single thermal treatment such as the first thermal treatment. In other embodiments, the acid generation process may be performed by the first thermal treatment and the acid diffusion process may be performed by the second diffusion process different from the first diffusion process. In yet other embodiments, the acid generation process may be performed by a radiation exposure and the acid diffusion process may be performed by the second diffusion process.

A width W₁₁ of the deprotected regions 220 of the mandrels 206 may be controlled by tuning the concentration of the free acid 218, diffusion coefficients of the free acid 218 in the mandrels 206 and 216, a process temperature of the thermal treatment, and/or process time of the thermal treatment. In some embodiments, the width W₁₁ may be controlled such that the width W₁₁ is less than a half of the width W₇ of the mandrels 206 (see FIG. 2D).

FIG. 2F illustrates an alternative embodiment, where the third polymer layer 214 is removed after the generation and diffusion of the free acid 218. In such embodiments, the third polymer layer 214 may be free from free acid and an agent-generating ingredient, such as a TAG. In some embodiments, the free acid 218 may be generated within the mandrels 216 and diffused into the mandrels 206 as described above with reference to FIG. 2E, and the description is repeated herein. After the formation of the deprotected regions 220 of the mandrels 206, the third polymer layer 214 is selectively removed to obtain the structure of FIG. 2E. In some embodiments, the third polymer layer 214 may be selectively removed as described above with reference to FIG. 2D, and the description is not repeated herein.

In FIG. 2G, the deprotected regions 220 of the mandrels 206 (see FIG. 2E) are selectively removed, leaving behind the mandrels 216 and the protected regions 222 of the mandrels 206. The removal process forms openings 230 that expose the target layer 204. The openings 230 may have a width W₁₂, which is equal to the width W₁₀ of the deprotected regions 220 of the mandrels 206 (see FIG. 2E).

In some embodiments, the selective removal may be accomplished using a second solvent. The second solvent may be same or different from the first solvent. The second solvent may be a positive-tone solvent and may be chosen to preferentially dissolve or etch away the deprotected regions 220 of the mandrels 206 (see FIG. 2E) while leaving the mandrels 216 and the protected regions 222 of the mandrels 206 substantially intact. In some embodiments, the second solvent may comprise methyl isobutyl carbinol (MIBC), isoamyl ether (IAE), Isobutyl Isobutyrate (IBIB), a combination thereof, or the like. After the selective removal, the mandrels 216 and the protected regions 222 of the mandrels 206 form a patterned mask 232 over the target layer 204.

In some embodiments, the width W₁₀ of the deprotected regions 220 of the mandrels 206 (see FIG. 2E) may be tuned such that a desired ratio of the width W₉ of the mandrels 216 to the width W₁₁ of the protected regions 222 of the mandrels 206 is achieved. In one embodiment, the width W₁₀ of the deprotected regions 220 (see FIG. 2E) of the mandrels 206 may be tuned such that the width W₉ of the mandrels 216 is same as the width W₁₁ of the protected regions 222 of the mandrels 206. In some embodiments, in addition to the width W₁₀ (see FIG. 2E), the width W₇ of the mandrels 206 and the width W₈ of the openings 208 (see FIG. 1A) may be also tuned such that the widths W₉, W₁₁, and W₁₂ are equal to each other.

In FIG. 2H, a pattern defined by the patterned mask 232 is transferred to the target layer 204 (see FIG. 2G), forming a patterned target layer 228. In some embodiments, the pattern transfer may be accomplished through an etching process. The etching process selectively removes portions of the target layer 204 that are not protected by the patterned mask 232, resulting in the formation of the patterned target layer 228. In some embodiments, the etching process may be a dry etching technique such as reactive ion etching (RIE), plasma etching, or ion beam etching. In other embodiments, wet etching techniques may be employed.

In some embodiment, the pattern transfer process may be followed by the removal of any remaining protected regions 222 and mandrels 216. The removal can be accomplished using suitable solvents, plasma ashing techniques, or the like leaving the patterned target layer 228 on the substrate 202. The resulting structure, with the patterned target layer 228, may form a component of a semiconductor device. Depending on the specific application, the patterned target layer 228 may represent various features of a semiconductor device, such as gate electrodes, interconnect lines, or other functional structures.

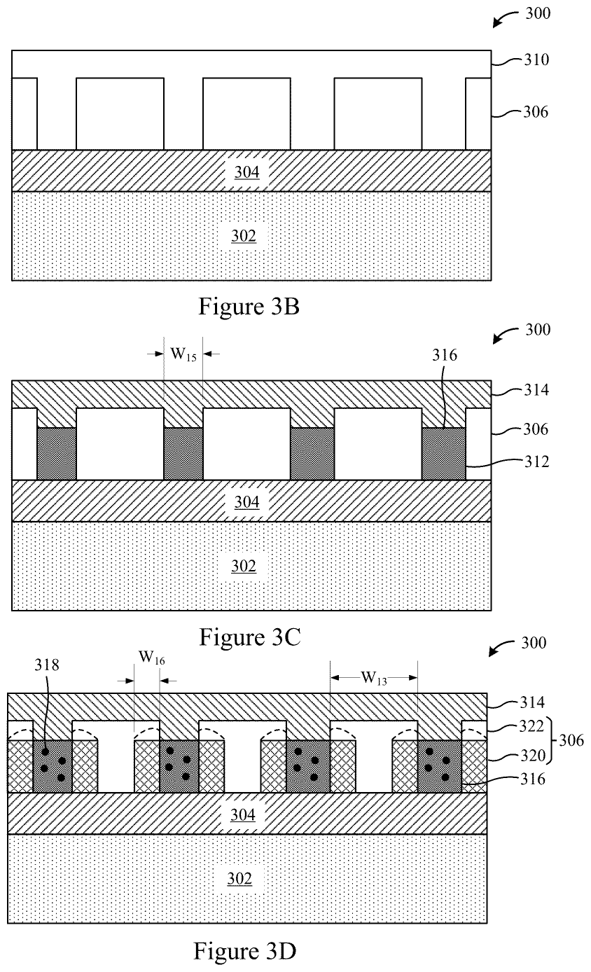

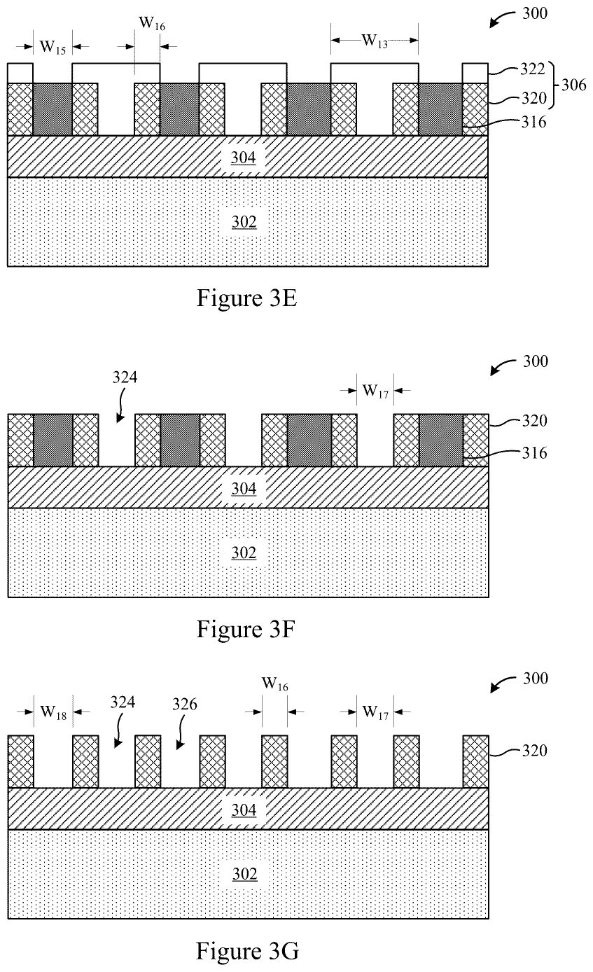

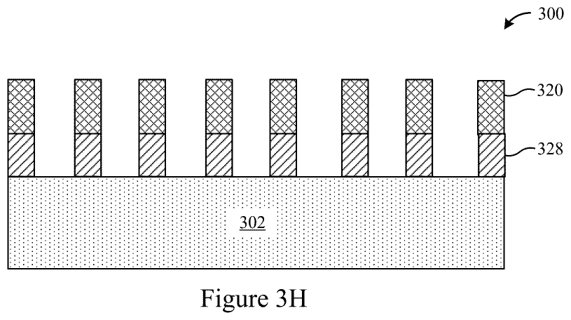

FIGS. 3A-3H illustrate cross-sectional views of intermediate stages in the manufacturing of a patterned mask over a substrate in accordance with various embodiments. Unless otherwise indicated, features 3xx may be similar to features 1xx of FIGS. 1A-1I, may be formed using materials and methods that are similar to those described above with reference to FIGS. 1A-1I, and descriptions of the similar features are not repeated herein.

In FIG. 3A, a semiconductor structure 300 is illustrated. The semiconductor structure 300 may include a substrate 302, a target layer 304 over the substrate 302, and a plurality of mandrels 306 over the target layer 304. The mandrels 306 may be separated by openings 308. The openings 308 define areas where the underlying target layer 304 is exposed. The mandrels 306 may have a width W₁₃ and the openings 308 may have a width W₁₄. The width W₁₃ may be same as or different from the width W₁₄.

In some embodiments, the dimensions, materials, and specific arrangements of the features of FIG. 3A may differ from those in FIG. 1A, depending on the particular application and desired outcomes of the patterning process. For example, the width and depth of the openings 308 and the width and height of the mandrels 306 may be adjusted to achieve different feature sizes in the final patterned structure.

In FIG. 3B, a first polymer layer 310 is formed over the mandrels 306. In the illustrated embodiment, the first polymer layer 310 overfills the openings 308 (see FIG. 3A), such that a top surface of the first polymer layer 310 is above top surfaces of the mandrels 306. This step is similar to the process described in FIG. 1B, but there may be differences in the specific properties or composition of the first polymer layer 310. For example, the first polymer layer 310 may comprise a mixture of a first polymer material and a second polymer material, such that relative amounts of the first polymer material and the second polymer material may be different from those of the first polymer layer 110 (see FIG. 1B). The first polymer material and the second material may have different physicochemical properties (e.g., different surface energies). In some embodiments, the first polymer material may comprise a polymer comprising a combination of monomer units including structures of moderate polarity such as hydroxy styrene, methyl methacrylate, and methyl acrylic acid, a combination thereof, or the like, and the second polymer material may comprise a polymer comprising a polymer comprising a combination of monomer units including structures of moderate polarity such as styrene, hydroxystyrene, methyl methacrylate, and methacrylic acid, a combination thereof, or the like, or a combination of monomer units including monomer units comprising acid labile groups such as t-butyloxycarbonyl (t-BOC), dioxolane (acetal), butylactone, a combination thereof, or the like. In some embodiments, the first polymer material may comprise free acid, or an agent-generating ingredient, such as a TAG or PAG. In some embodiments, the second polymer material may comprise free acid, or an agent-generating ingredient, such as a TAG or PAG, or may be free from free acid and the agent-generating ingredient.

In FIG. 3C, the first polymer layer 310 (see FIG. 3B) separates into a second polymer layer 312 comprising the first polymer material and a third polymer layer 314 comprising a second polymer material, such that the third polymer layer 314 is over the second polymer layer 312. The second polymer layer 312 may be also referred to as an acid trim layer and the third polymer layer 314 may be also referred to as an embedded barrier layer. In some embodiments, this separation may occur due to differences in the physicochemical properties (e.g., surface energy) of the components in the first polymer layer 310 (see FIG. 3B). The relative contents of the first polymer material and the second polymer material within the first polymer layer 310 may control the thicknesses of the second polymer layer 312 and the third polymer layer 314 and a position of an interface between the second polymer layer 312 and the third polymer layer 314.

In the illustrated embodiment, the interface between the second polymer layer 312 and the third polymer layer 314 is below the top surfaces of the mandrels 306, such that the second polymer layer 312 partially fills the openings 308 (see FIG. 3A) and the third polymer layer 314 is formed over the second polymer layer 312 and the mandrels 306. In some embodiments, the first polymer layer 310 (see FIG. 3B) may be self-separated into the second polymer layer 312 and the third polymer layer 314. In other embodiments, the separation of the first polymer layer 310 into the second polymer layer 312 and the third polymer layer 314 may be induced by a thermal treatment, exposure to specific solvents, or other processing conditions. Portions of the second polymer layer 312 that partially fill the openings 308 (see FIG. 3A) form mandrels 316. Accordingly, the mandrels 316 may have a width W₁₅ that is equal to the width W₁₄ of the openings 308 (see FIG. 3A). Furthermore, in the illustrated embodiment, a height of the mandrels 316 is less than a height of the mandrels 306.

In FIG. 3D, a post-deposition bake process may be performed to remove any solvents and stabilize the second polymer layer 312 and the third polymer layer 314. The post-deposition bake process may be performed at a process temperature in a range from 75 °C to 100 °C for a process time in a range from 30 seconds to 180 seconds.

In some embodiments, the post-deposition bake process may also generate free acid 318 in the mandrels 316 and/or diffuse the free acid 318 into the mandrels 306. In such embodiments, the third polymer layer 314 may be free from free acid and an agent-generating ingredient, such as a TAG or PAG, or may comprise a TAG that has an activation temperature that is greater than the process temperature of the post-deposition bake process, and the mandrels 316 may comprises free acid 318 or a TAG that has an activation temperature that is less than the process temperature of the post-deposition bake process.

In some embodiments, following the generation of the free acid 318, the free acid 318 may diffuse from the mandrels 316 into the mandrels 306. The diffused free acid 318 reacts with the material of the mandrels 306 to create deprotected regions 320 within the mandrels 306. Remaining regions of the mandrels 306 form protected regions 322 of the mandrels 306. The deprotected regions 320 of the mandrels 306 may have different chemical properties (e.g., solubility in various solvents) compared to the protected regions 322 of the mandrels 306.

A width W₁₆ of the deprotected regions 320 of the mandrels 306 may be controlled by tuning a concentration of the free acid 318, diffusion coefficients of the free acid 318 in the mandrels 306 and 316, a process temperature of the post-deposition bake process, and/or a process time of the post-deposition bake process. In some embodiments, the width W₁₆ may be controlled such that the width W₁₆ is less than a half of the width W₁₃ of the mandrels 306.

The height of the deprotected regions 320 of the mandrels 306 may be controlled by tuning the height of the mandrels 316, which in turn is controlled by tuning the composition of the first polymer layer 310 (see FIG. 3B). Based on diffusion properties of the free acid 318 within the mandrels 306, a shape of top surfaces of the deprotected regions 320 of the mandrels 306 may be altered. In some embodiments, the top surfaces of the deprotected regions 320 of the mandrels 306 may be substantially flat or planar. In other embodiments, the top surfaces of the deprotected regions 320 of the mandrels 306 may be curved as illustrated by dashed lines in FIG. 3D.

In FIG. 3E, the third polymer layer 314 (see FIG. 3D) is selectively removed, leaving the mandrels 306 and 316 substantially intact. In some embodiments, the selective removal of the third polymer layer 314 may be accomplished using a first solvent that preferentially dissolves or etches the third polymer layer 314 without substantially affecting the mandrels 306 and 316. The choice of the first solvent depends on the specific compositions of the mandrels 306 and 316, and the third polymer layer 314. In an embodiment, tetramethylammonium hydroxide (TMAH) may be used as the first solvent for the selective removal process.

In FIG. 3F, the protected regions 322 of the mandrels 306 (see FIG. 3E) are selectively removed, leaving behind the mandrels 316 and the deprotected regions 320 of the mandrels 306. The removal process forms openings 324 that expose the target layer 304. The openings 324 may have a width W₁₇, which is equal to a difference between the width W₁₃ of the mandrels 306 and twice the width W₁₆ of the deprotected regions 320 of the mandrels 306 (see FIG. 3E).

In some embodiments, the selective removal may be accomplished using a second solvent. The second solvent may be different from the first solvent. The second solvent may be a negative-tone solvent and may be chosen to preferentially dissolve or etch away the protected regions 322 of the mandrels 306 (see FIG. 3E) while leaving the mandrels 316 and the deprotected regions 320 of the mandrels 306 substantially intact. In some embodiments, the second solvent may comprise methyl isobutyl carbinol (MIBC), isoamyl ether (IAE), Isobutyl Isobutyrate (IBIB), a combination thereof, or the like.

In FIG. 3G, the mandrels 316 (see FIG. 3F) are selectively removed, leaving behind the deprotected regions 320 of the mandrels 306. The removal process forms openings 326 that expose the target layer 304. In some embodiments, the openings 326 may have a width W₁₈, which is equal to the width W₁₄ of the openings 308 (see FIG. 3A) and the width W₁₅ if the mandrels 316 (see FIG. 3E).

In some embodiments, the selective removal may be accomplished using a third solvent. The third solvent may be chosen to preferentially dissolve or etch away the mandrels 316 (see FIG. 3F) while leaving the deprotected regions 320 of the mandrels 306 substantially intact. In some embodiments, the third solvent may comprise methyl isobutyl carbinol (MIBC), isoamyl ether (IAE), Isobutyl Isobutyrate (IBIB), a combination thereof, or the like.

In some embodiments, materials of the mandrels 306 (see FIG. 3E) and the mandrels 316 (see FIG. 3F) may be chosen such that the third solvent used for removing the mandrels 316 (see FIG. 3F) may be the same as the second solvent used for removing the protected regions 322 of the mandrels 306 (see FIG. 3E). In other embodiments, the third solvent may be different from the second solvent.

After the selective removal, the deprotected regions 320 of the mandrels 306 form a patterned mask over the target layer 304. The dimensions (e.g., width W₁₆) of the deprotected regions 320 of the mandrels 306 may be smaller than the dimensions (e.g., width W₁₄) the openings 308 (see FIG. 3A). This reduction in feature size is a result of the controlled acid diffusion process and can be used to achieve patterns with dimensions smaller than those directly achievable through the initial lithography process.

In some embodiments, the width W₁₆ deprotected regions 320 of the mandrels 306 may be tuned such that a desired ratio of the width W₁₇ of the openings 324 to the width W₁₈ of the openings 326 is achieved. In one embodiment, the width W₁₆ deprotected regions 320 of the mandrels 306 may be tuned such that the width W₁₇ of the openings 324 is same as the width W₁₈ of the openings 326. In some embodiments, in addition to the width W₁₆, the width W₁₃ of the mandrels 306 and the width W₁₄ of the openings 308 (see FIG. 3A) may be also tuned such that the widths W₁₆, W₁₇, and W₁₈ are equal to each other.

In FIG. 3H, a pattern defined by the patterned mask (formed by the deprotected regions 320 of the mandrels 306) is transferred to the target layer 304 (see FIG. 3G), forming a patterned target layer 328. In some embodiments, the pattern transfer may be accomplished through an etching process. The etching process selectively removes portions of the target layer 304 (see FIG. 3G) that are not protected by the patterned mask, resulting in the formation of the patterned target layer 328. In some embodiments, the etching process may be a dry etching technique such as reactive ion etching (RIE), plasma etching, or ion beam etching. In other embodiments, wet etching techniques may be employed.

In some embodiment, the pattern transfer process may be followed by the removal of any remaining deprotected regions 320. The removal can be accomplished using suitable solvents, plasma ashing techniques, or the like leaving the patterned target layer 328 on the substrate 302. The resulting structure, with the patterned target layer 328, may form a component of a semiconductor device. Depending on the specific application, the patterned target layer 328 may represent various elements of a semiconductor device, such as gate electrodes, interconnect lines, or other functional structures.

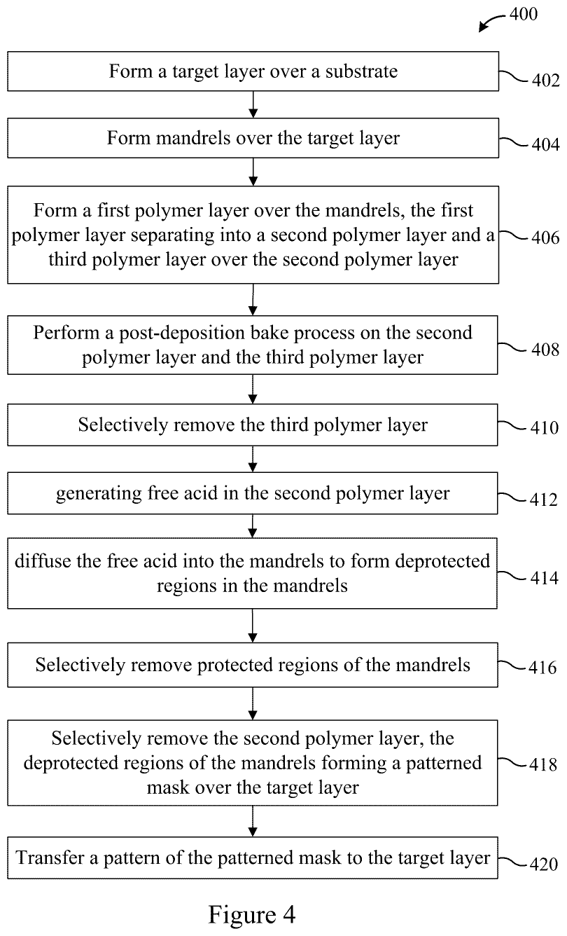

FIG. 4 illustrates a flow diagram of a method 500 for forming a patterned mask over a substrate in accordance with various embodiments. In step 402, a target layer (e.g., target layer 104) is formed over a substrate (e.g., substrate 102), as described above with reference to FIG. 1A. In step 404, mandrels (e.g., mandrels 106) are formed over the target layer (e.g., target layer 104), as described above with reference to FIG. 1A. In step 406, a first polymer layer (e.g., first polymer layer 110) is formed over the mandrels (e.g., mandrels 106), such that the first polymer layer (e.g., first polymer layer 110) separates into a second polymer layer (e.g., second polymer layer 112) and a third polymer layer (e.g., third polymer layer 114) over the second polymer layer (e.g., second polymer layer 112), as described above with reference to FIGS. 1B and 1C.

In step 408, a post-deposition bake process is performed on the second polymer layer (e.g., second polymer layer 112) and the third polymer layer (e.g., third polymer layer 114), as described above with reference to FIG. 1C. In step 410, the third polymer layer (e.g., third polymer layer 114) is selectively removed, as described above with reference to FIG. 1D. In step 412, free acid (e.g., free acid 118) is generated in the second polymer layer (e.g., mandrels 116), as described above with reference to FIG. 1E. In step 414, the free acid (e.g., free acid 118) is diffused into the mandrels (e.g., mandrels 106) to form deprotected regions (e.g., deprotected regions 120) in the mandrels (e.g., mandrels 106), as described above with reference to FIG. 1E.

In step 416, protected regions (e.g., protected regions 122) of the mandrels (e.g., mandrels 106) are selectively removed, as described above with reference to FIG. 1G. In step 418, the second polymer layer (e.g., mandrels 116) is selectively removed, with the deprotected regions (e.g., deprotected regions 120) of the mandrels (e.g., mandrels 106) forming a patterned mask over the target layer (e.g., target layer 104), as described above with reference to FIG. 1H. In step 420, a pattern of the patterned mask is transferred to the target layer (e.g., target layer 104), as described above with reference to FIG. 1I. In the illustrated embodiment, step 410 is performed after step 408 and before step 412. In other embodiments, step 410 may be performed after step 414 and before step 416.

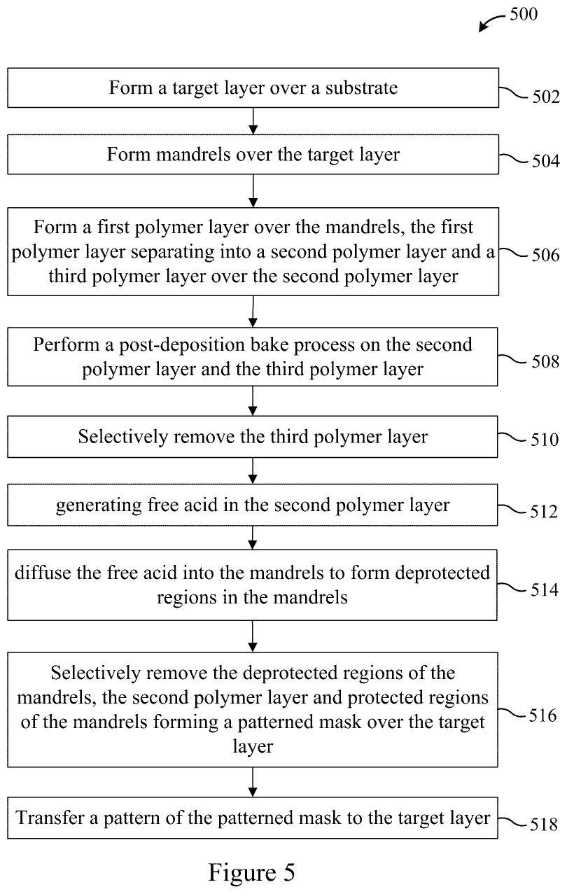

FIG. 5 illustrates a flow diagram of a method 500 for forming a patterned mask over a substrate in accordance with various embodiments. In step 502, a target layer (e.g., target layer 204) is formed over a substrate (e.g., substrate 202), as described above with reference to FIG. 2A. In step 504, mandrels (e.g., mandrels 206) are formed over the target layer (e.g., target layer 204), as described above with reference to FIG. 2A. In step 506, a first polymer layer (e.g., first polymer layer 210) is formed over the mandrels (e.g., mandrels 206), such that the first polymer layer (e.g., first polymer layer 210) separates into a second polymer layer (e.g., second polymer layer 212) and a third polymer layer (e.g., third polymer layer 214) over the second polymer layer (e.g., second polymer layer 212), as described above with reference to FIGS. 2B and 2C.

In step 508, a post-deposition bake process is performed on the second polymer layer (e.g., second polymer layer 212) and the third polymer layer (e.g., third polymer layer 214), as described above with reference to FIG. 2C. In step 510, the third polymer layer (e.g., third polymer layer 214) is selectively removed, as described above with reference to FIG. 2D. In step 512, free acid (e.g., free acid 218) is generated in the second polymer layer (e.g., mandrels 216), as described above with reference to FIG. 2E. In step 514, the free acid (e.g., free acid 218) is diffused into the mandrels (e.g., mandrels 206) to form deprotected regions (e.g., deprotected regions 220) in the mandrels (e.g., mandrels 206), as described above with reference to FIG. 2E.

In step 516, the deprotected regions (e.g., deprotected regions 220) of the mandrels (e.g., mandrels 206) are selectively removed, with the second polymer layer (e.g., mandrels 216) and protected regions (e.g., protected regions 222) of the mandrels (e.g., mandrels 206) forming a patterned mask (e.g., patterned mask 232) over the target layer (e.g., target layer 204), as described above with reference to FIG. 2G. In step 518, a pattern of the patterned mask (e.g., patterned mask 232) is transferred to the target layer (e.g., target layer 204), as described above with reference to FIG. 2H. In the illustrated embodiment, step 510 is performed after step 508 and before step 512. In other embodiments, step 510 may be performed after step 514 and before step 516.

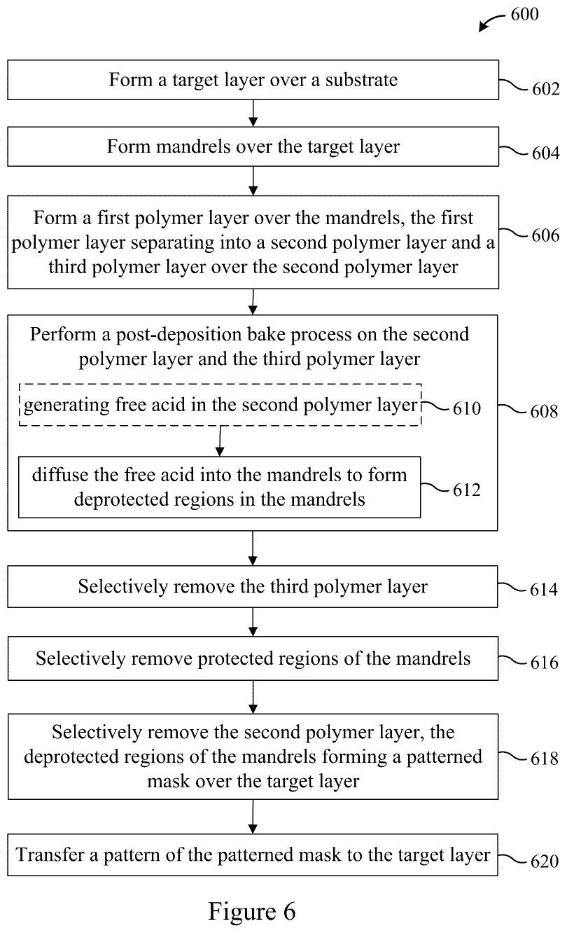

FIG. 6 illustrates a flow diagram of a method 600 for forming a patterned mask over a substrate in accordance with various embodiments. In step 602, a target layer (e.g., target layer 304) is formed over a substrate (e.g., substrate 302), as described above with reference to FIG. 3A. In step 604, mandrels (e.g., mandrels 306) are formed over the target layer (e.g., target layer 304), as described above with reference to FIG. 3A. In step 606, a first polymer layer (e.g., first polymer layer 310) is formed over the mandrels (e.g., mandrels 306), such that the first polymer layer (e.g., first polymer layer 310) separates into a second polymer layer (e.g., second polymer layer 312) and a third polymer layer (e.g., third polymer layer 314) over the second polymer layer (e.g., second polymer layer 312), as described above with reference to FIGS. 3B and 3C.

In step 608, a post-deposition bake process is performed on the second polymer layer (e.g., second polymer layer 312) and the third polymer layer (e.g., third polymer layer 314), as described above with reference to FIG. 3D. Step 608 may comprise steps 610 and 612. In step 610, free acid (e.g., free acid 318) is generated in the second polymer layer (e.g., mandrels 316), as described above with reference to FIG. 3D. In other embodiments, step 610 may be omitted. In step 612, the free acid (e.g., free acid 318) is diffused into the mandrels (e.g., mandrels 306) to form deprotected regions (e.g., deprotected regions 320) in the mandrels (e.g., mandrels 306), as described above with reference to FIG. 3D.

In step 614, the third polymer layer (e.g., third polymer layer 314) is selectively removed, as described above with reference to FIG. 3E. In step 616, protected regions (e.g., protected regions 322) of the mandrels (e.g., mandrels 306) are selectively removed, as described above with reference to FIG. 3F. In step 618, the second polymer layer (e.g., mandrels 316) is selectively removed, with the deprotected regions (e.g., deprotected regions 320) of the mandrels (e.g., mandrels 306) forming a patterned mask over the target layer (e.g., target layer 304), as described above with reference to FIG. 3G. In step 620, a pattern of the patterned mask is transferred to the target layer (e.g., target layer 304), as described above with reference to FIG. 3H.

Example embodiments of the disclosure are described below. Other embodiments can also be understood from the entirety of the specification as well as the claims filed herein.

Example 1. A method including: forming mandrels over a substrate; forming a first polymer layer over the mandrels, a top surface of the first polymer layer being above top surfaces of the mandrels; separating the first polymer layer into a second polymer layer and a third polymer layer over the second polymer layer, an interface between the second polymer layer and the third polymer layer being below the top surfaces of the mandrels; selectively removing the third polymer layer; generating free acid in the second polymer layer; diffusing the free acid into the mandrels to form deprotected regions of the mandrels, remaining regions of the mandrels forming protected regions of the mandrels; selectively removing the protected regions of the mandrels; and selectively removing the second polymer layer, where the deprotected regions of the mandrels form a patterned mask over the substrate.

Example 2. The method of example 1, where generating the free acid in the second polymer layer includes subjecting the second polymer layer to a thermal treatment or an actinic radiation.

Example 3. The method of any of examples 1 and 2, where the protected regions of the mandrels and the second polymer layer are selectively removed using a same solvent.

Example 4. The method of any of examples 1 to 3, where the protected regions of the mandrels and the second polymer layer are selectively removed using different solvents.

Example 5. The method of any of examples 1 to 4, where generating and diffusing the free acid includes performing a post-deposition bake on the second polymer layer.

Example 6. The method of any of examples 1 to 5, further including: before forming the mandrels over the substrate, forming a target layer over the substrate; and after forming the patterned mask, transferring a pattern of the patterned mask to the target layer.

Example 7. The method of any of examples 1 to 6, where the third polymer layer is selectively removed after diffusing the free acid into the mandrels and before selectively removing the protected regions of the mandrels.

Example 8. A method including: depositing mandrels over a substrate, the mandrels being separated by openings; depositing a first polymer layer over the mandrels, the first polymer layer overfilling the openings; separating the first polymer layer into a second polymer layer and a third polymer layer over the second polymer layer, an interface between the second polymer layer and the third polymer layer being below top surfaces of the mandrels; selectively removing the third polymer layer suing a first solvent; generating free acid in the second polymer layer; diffusing the free acid into the mandrels to form deprotected regions of the mandrels, remaining regions of the mandrels forming protected regions of the mandrels; selectively removing the protected regions of the mandrels using a second solvent different from the first solvent; and selectively removing the second polymer layer using a third solvent different from the first solvent, where the deprotected regions of the mandrels form a patterned mask over the substrate.

Example 9. The method of example 8, where the second solvent is same as the third solvent.

Example 10. The method of any of examples 8 and 9, where the second solvent is different from the third solvent.

Example 11. The method of any of examples 8 to 10, where: generating the free acid in the second polymer layer includes subjecting the second polymer layer to an actinic radiation; and diffusing the free acid into the mandrels comprises subjecting the second polymer layer to a thermal treatment.

Example 12. The method of any of examples 8 to 11, where: generating the free acid in the second polymer layer includes subjecting the second polymer layer to a thermal treatment; and diffusing the free acid into the mandrels comprises subjecting the second polymer layer to the thermal treatment.

Example 13. The method of any of examples 8 to 12, further including, before generating the free acid in the second polymer layer, perform a post-deposition bake on the second polymer layer.

Example 14. The method of any of examples 8 to 13, where the thermal treatment is performed at a higher temperature than the post-deposition bake.

Example 15. A method including: forming mandrels over a substrate; forming a first polymer layer over the mandrels, a top surface of the first polymer layer being above top surfaces of the mandrels; separating the first polymer layer into a second polymer layer and a third polymer layer over the second polymer layer, an interface between the second polymer layer and the third polymer layer being at the top surfaces of the mandrels; selectively removing the third polymer layer using a first solvent; generating free acid in the second polymer layer; diffusing the free acid into the mandrels to form deprotected regions of the mandrels, remaining regions of the mandrels forming protected regions of the mandrels; and selectively removing the deprotected regions of the mandrels using a second solvent, where the second polymer layer and the protected regions of the mandrels form a patterned mask over the substrate.

Example 16. The method of example 15, where the first solvent is same as the second solvent.

Example 17. The method of any of examples 15 and 16, where the second solvent is different from the second solvent.

Example 18. The method of any of examples 15 to 17, where forming the first polymer layer over the mandrels includes depositing a mixture of a first polymer material and a second polymer material over the mandrels, the first polymer material being different from the second polymer material.

Example 19. The method of any of examples 15 to 18, further including: before forming the mandrels over the substrate, forming a target layer over the substrate; and after forming the patterned mask, transferring a pattern of the patterned mask to the target layer.

Example 20. The method of any of examples 15 to 19, where generating and diffusing the free acid includes performing a thermal process on the second polymer layer.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method comprising:
forming mandrels over a substrate;
forming a first polymer layer over the mandrels, a top surface of the first polymer layer being above top surfaces of the mandrels;
separating the first polymer layer into a second polymer layer and a third polymer layer over the second polymer layer, an interface between the second polymer layer and the third polymer layer being below the top surfaces of the mandrels;
selectively removing the third polymer layer;
generating free acid in the second polymer layer;
diffusing the free acid into the mandrels to form deprotected regions of the mandrels, remaining regions of the mandrels forming protected regions of the mandrels;
selectively removing the protected regions of the mandrels; and
selectively removing the second polymer layer, wherein the deprotected regions of the mandrels form a patterned mask over the substrate.

2. The method of claim 1, wherein generating the free acid in the second polymer layer comprises subjecting the second polymer layer to a thermal treatment or an actinic radiation.

3. The method of claim 1, wherein the protected regions of the mandrels and the second polymer layer are selectively removed using a same solvent.

4. The method of claim 1, wherein the protected regions of the mandrels and the second polymer layer are selectively removed using different solvents.

5. The method of claim 1, wherein generating and diffusing the free acid comprises performing a post-deposition bake on the second polymer layer.

6. The method of claim 1, further comprising:
before forming the mandrels over the substrate, forming a target layer over the substrate; and
after forming the patterned mask, transferring a pattern of the patterned mask to the target layer.

7. The method of claim 1, wherein the third polymer layer is selectively removed after diffusing the free acid into the mandrels and before selectively removing the protected regions of the mandrels.

8. A method comprising:
depositing mandrels over a substrate, the mandrels being separated by openings;
depositing a first polymer layer over the mandrels, the first polymer layer overfilling the openings;
separating the first polymer layer into a second polymer layer and a third polymer layer over the second polymer layer, an interface between the second polymer layer and the third polymer layer being below top surfaces of the mandrels;
selectively removing the third polymer layer suing a first solvent;
generating free acid in the second polymer layer;
diffusing the free acid into the mandrels to form deprotected regions of the mandrels, remaining regions of the mandrels forming protected regions of the mandrels;
selectively removing the protected regions of the mandrels using a second solvent different from the first solvent; and
selectively removing the second polymer layer using a third solvent different from the first solvent, wherein the deprotected regions of the mandrels form a patterned mask over the substrate.

9. The method of claim 8, wherein the second solvent is same as the third solvent.

10. The method of claim 8, wherein the second solvent is different from the third solvent.

11. The method of claim 8, wherein:
generating the free acid in the second polymer layer comprises subjecting the second polymer layer to an actinic radiation; and
diffusing the free acid into the mandrels comprises subjecting the second polymer layer to a thermal treatment.

12. The method of claim 8, wherein:
generating the free acid in the second polymer layer comprises subjecting the second polymer layer to a thermal treatment; and
diffusing the free acid into the mandrels comprises subjecting the second polymer layer to the thermal treatment.

13. The method of claim 12, further comprising, before generating the free acid in the second polymer layer, perform a post-deposition bake on the second polymer layer.

14. The method of claim 13, wherein the thermal treatment is performed at a higher temperature than the post-deposition bake.

15. A method comprising:
forming mandrels over a substrate;
forming a first polymer layer over the mandrels, a top surface of the first polymer layer being above top surfaces of the mandrels;
separating the first polymer layer into a second polymer layer and a third polymer layer over the second polymer layer, an interface between the second polymer layer and the third polymer layer being at the top surfaces of the mandrels;
selectively removing the third polymer layer using a first solvent;
generating free acid in the second polymer layer;
diffusing the free acid into the mandrels to form deprotected regions of the mandrels, remaining regions of the mandrels forming protected regions of the mandrels; and
selectively removing the deprotected regions of the mandrels using a second solvent, wherein the second polymer layer and the protected regions of the mandrels form a patterned mask over the substrate.

16. The method of claim 15, wherein the first solvent is same as the second solvent.

17. The method of claim 15, wherein the second solvent is different from the second solvent.

18. The method of claim 15, wherein forming the first polymer layer over the mandrels comprises depositing a mixture of a first polymer material and a second polymer material over the mandrels, the first polymer material being different from the second polymer material.

19. The method of claim 15, further comprising:
before forming the mandrels over the substrate, forming a target layer over the substrate; and
after forming the patterned mask, transferring a pattern of the patterned mask to the target layer.

20. The method of claim 15, wherein generating and diffusing the free acid comprises performing a thermal process on the second polymer layer.
